(19) United States
(12) Patent Application Publication
(10) Pub. No.: US 2026/0363122 A1
(43) Pub. Date: Nov. 12, 2026

(54) CIRCUIT BOARD, METHOD OF MANUFACTURING THE SAME, AND ELECTRONIC COMPONENT INCLUDING THE SAME

(71) Applicant: SAMSUNG ELECTRO-MECHANICS CO., LTD., Suwon-si (KR)

(72) Inventors: Inkwan KIM, Suwon-si (KR); Kwang Rok CHOI, Suwon-si (KR); Yeongmin BAE, Suwon-si (KR)

(73) Assignee: SAMSUNG ELECTRO-MECHANICS CO., LTD., Suwon-si (KR)

(21) Appl. No.: 19/448,295

(22) Filed: Jan. 14, 2026

(30) Foreign Application Priority Data
Apr. 30, 2025 (KR) 10-2025-0057051
Sep. 15, 2025 (KR) 10-2025-0131801

(51) Int. Cl. H10W 70/695; H10W 70/05

(52) U.S. Cl. CPC H10W 70/695; H10W 70/05

(57) ABSTRACT

A method of manufacturing a printed circuit board includes applying an insulating resin to form an insulating resin layer, performing a first curing of the insulating resin layer, forming a circuit wiring on the first-cured insulating resin layer, forming an organic surface treatment coating film by performing a surface treatment on the insulating resin layer and the circuit wiring, and baking the insulating resin layer and the circuit wiring on which the organic surface treatment coating film is formed. Baking promotes covalent O—C═O bonding between the insulating resin layer and the coating film, and the surface treatment forms a coordinate bond between copper wiring and imidazole of the coating film, thereby improving adhesion and reducing peel-off defects—particularly in regions lacking solder resist.

### CROSS-REFERENCE TO RELATED APPLICATION

This application claims priority to and the benefit of Korean Patent Application No. 10-2025-0131801 filed with the Korean Intellectual Property Office on Sep. 15, 2025, and Korean Patent Application No. 10-2025-0057051 filed with the Korean Intellectual Property Office on Apr. 30, 2025, the entire contents of which are incorporated herein by reference in their entireties.

### BACKGROUND

### (a) Field

The present disclosure relates to a circuit board, a method of manufacturing a circuit board, and an electronic component package including a circuit board.

### (b) Description of the Related Art

In semiconductor package substrate manufacturing, a range of technologies have been developed to enhance surface adhesion and mitigate peeling and reliability issues caused by coefficient of thermal expansion (CTE) mismatches between dissimilar materials. Common approaches include annealing to narrow effective CTE differences, adjusting substrate surface roughness, and optimizing process parameters to strengthen interfacial bonding. Although these methods deliver incremental improvements, they remain insufficient to fully address the demands of continued microcircuit scaling and the high levels of integration now required in advanced package substrates.

In certain automotive package designs, solder resist (SR) is deliberately omitted in local areas, leaving portions of the circuit pattern exposed. In such structures, uncovered copper (Cu) wiring is more susceptible to peel-off under external impact or mechanical stress, and the root cause can be difficult to isolate, creating persistent quality risks. Thus, there is a need for improved automotive package designs that reduce mechanical and thermal interfacial stresses, protects Cu traces from external damage, and thereby lowers the incidence of peel-off defects.

### SUMMARY

One of the various objectives of the present disclosure is to prevent a wiring of a printed circuit board from peeling or dropping off.

One of the various objectives of the present disclosure is to improve the adhesion between a wiring of a printed circuit board and a lower insulating layer thereof.

A method of manufacturing a printed circuit board according to an embodiment of the present disclosure may include applying an insulating resin to form an insulating resin layer, performing a first curing of the insulating resin layer, forming a circuit wiring on the first cured insulating resin layer, forming a surface treatment coating film by performing a surface treatment on the insulating resin layer and the circuit wiring, and baking the insulating resin layer and the circuit wiring on which the surface treatment coating film is formed.

An electronic component package according to an embodiment of the present disclosure may include an insulating resin layer, a circuit wiring disposed on the insulating resin layer, a surface treatment coating film disposed on the insulating resin layer and the circuit wiring, and wherein an O—C═O bond is formed between the insulating resin layer and the surface treatment coating film.

As one of the effects of the present disclosure, it is possible to provide a printed circuit board with improved adhesion between a wiring of a printed circuit board and a lower insulating layer thereof.

As one of the effects of the present disclosure, it is possible to provide a printed circuit board in which a wiring is prevented from peeling or dropping off.

### BRIEF DESCRIPTION OF THE DRAWINGS

FIG. 1 is a block diagram schematically illustrating an example of an electronic device system.

FIG. 2 is a perspective view schematically illustrating an example of an electronic device.

FIG. 3 is a cross-sectional view schematically illustrating a printed circuit board according to an embodiment.

FIG. 4 is a cross-sectional view schematically illustrating a method of manufacturing a printed circuit board according to an embodiment.

FIG. 5 is a cross-sectional view schematically illustrating a method of manufacturing a printed circuit board according to an embodiment.

FIG. 6 is a cross-sectional view schematically illustrating a method of manufacturing a printed circuit board according to an embodiment.

FIG. 7 is a cross-sectional view schematically illustrating a method of manufacturing a printed circuit board according to an embodiment.

FIG. 8 is a conceptual view illustrating a chemical bond formed between an insulating resin layer, a circuit wiring, and a surface treatment coating film of a printed circuit board according to an embodiment.

FIG. 9 is a graph illustrating that the remaining epoxy functional group decreases as the steps of a second curing of the insulating resin layer, formation of a surface treatment coating film, and baking treatment are performed.

FIG. 10 is a graph illustrating that the O—C═O bond increases as the steps of a second curing of the insulating resin layer, formation of a surface treatment coating film, and baking treatment are performed.

### DETAILED DESCRIPTION OF THE EMBODIMENTS

Hereinafter, various embodiments of the present disclosure will be described in detail so that a person of ordinary skill in the technical field to which the present disclosure belongs can easily implement it with reference to the accompanying drawings. Embodiments may be implemented in various different forms and are not limited to the embodiments described herein. In order to clearly describe the present disclosure, parts unrelated to the description are omitted in the drawings, and the same reference numerals are designated to the same or similar components throughout the specification.

In addition, the size and thickness of each component shown in the drawings are arbitrarily illustrated for convenience of description, so the embodiments are not necessarily limited to those illustrated. The thickness is enlarged to clearly represent the various layers and regions in the drawings. In the drawings, for convenience of description, the thickness of some layers and areas is exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Furthermore, in the specification, the word “on” or “above” means positioned on or below the object portion and does not necessarily mean positioned on the upper side of the object portion based on a gravitational direction.

In addition, throughout the specification, when a part is described as comprising or including a component, this means, unless otherwise stated to the contrary, that it does not exclude other components but may further include other components.

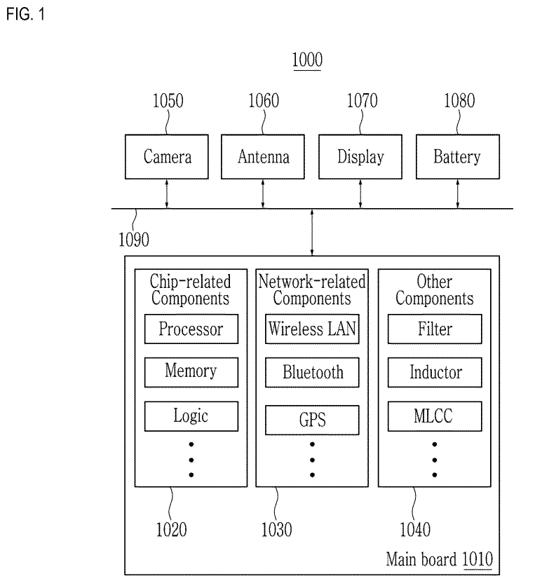

FIG. 1 is a block diagram schematically illustrating an example of an electronic device system.

Referring to FIG. 1, an electronic device 1000 accommodates a main board 1010. A chip-related component 1020, a network-related component 1030, and other components 1040 are physically and/or electrically connected to the main board 1010. These are also coupled with other electronic components to be described later to form various signal lines 1090.

The chip-related components 1020 may include memory chips such as volatile memory (e.g., DRAM), non-volatile memory (e.g., ROM), flash memory, and the like, application processor chips such as central processors (e.g., CPU), graphics processors (e.g., GPU), digital signal processors, encryption processors, microprocessors, microcontrollers, and the like, and logic chips such as analog-to-digital converters, application-specific ICs (ASICs), and the like, but is not limited thereto, other types of chip-related electronic components may also be included. In addition, the chip-related components 1020 may be combined with each other. The chip-related components 1020 may be in the form of a package including the above-described chips or electronic components.

Network-related components 1030 may include, but are not limited to, Wi-Fi (such as IEEE 802.11 family), WiMAX (such as IEEE 802.16 family), IEEE 802.20, LTE (long term evolution), Ev-DO, HSPA+, HSDPA+, HSUPA+, EDGE, GSM, GPS, GPRS, CDMA, TDMA, DECT, Bluetooth, 3G, 4G, 5G, and any other wireless and wired protocols or protocols designated thereafter. In addition, the network-related component 1030 may be combined with the chip-related components 1020.

The other components 1040 may include high-frequency inductors, ferrite inductors, power inductors, ferrite beads, low temperature co-firing ceramics (LTCC), electro-magnetic interference (EMI) filters, and MLCC (Multi-Layer Ceramic Capacitor). However, the other components may include, but are not limited thereto, passive devices in the form of a chip component used for various other purposes. In addition, the other components 1040 may be combined with chip-related components 1020 and/or network-related components 1030.

Depending on the type of the electronic device 1000, the electronic device 1000 may include other electronic components that may or may not be physically and/or electrically connected to the main board 1010. For example, the other electronic components may include a camera module 1050, an antenna module 1060, a display 1070, and a battery 1080. However, the other electronic components may include, but are not limited thereto, audio codecs, video codecs, power amplifiers, compasses, accelerometers, gyroscopes, speakers, mass storage devices (e.g., hard disk drives), compact disks (CDs), and digital virtual disks (DVDs). In addition, other electronic components used for various purposes may be included depending on the type of the electronic device 1000.

The electronic device 1000 may be a smartphone, a personal information terminal, a digital video camera, a digital still camera, a network system, a computer, a monitor, a tablet, a laptop, a netbook, a television, a video game, a smart watch, an automated, and the like. However, the electronic device 1000 is not limited thereto, and may be any other electronic device that processes data in addition to these.

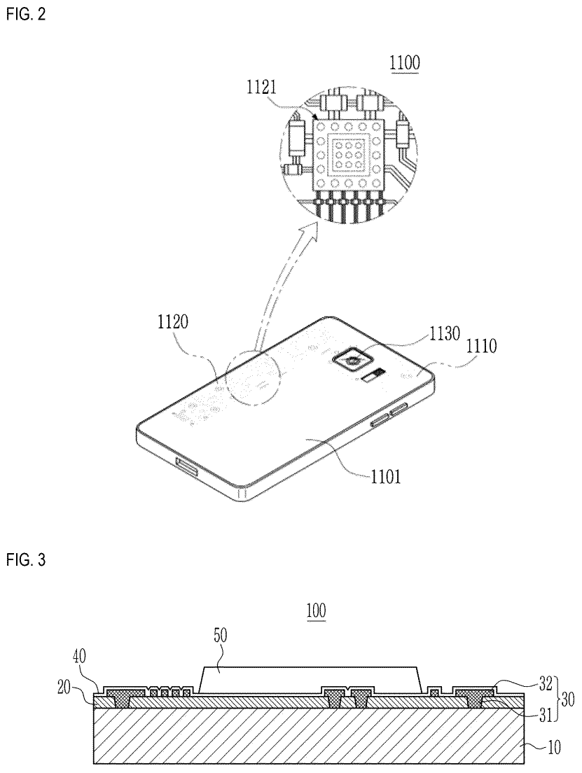

FIG. 2 is a perspective view schematically illustrating an example of an electronic device.

Referring to FIG. 2, the electronic device may be, for example, a smartphone 1100. A mother board 1110 may be accommodated inside the smartphone 1100, and various components 1120 may be physically and/or electrically connected to the mother board 1110. In addition, other components that may or may not be physically and/or electrically connected to the motherboard 1110, such as the camera module 1130 and/or speaker 1140, may be accommodated inside. Some of the components 1120 may be the chip-related components described above, for example, the component package 1121, but are not limited thereto. The component package 1121 may include a printed circuit board in which an electronic component including an active component and/or a passive component is surface-mounted. Alternatively, the component package 1121 may include a printed circuit board in which active and/or passive components are embedded. Meanwhile, the electronic device is not necessarily limited to the smartphone 1100 and may be another electronic device as described above.

FIG. 3 is a cross-sectional view schematically illustrating a printed circuit board according to an embodiment.

Referring to FIG. 3, a printed circuit board 100 according to an embodiment may include a base substrate 10, an insulating resin layer 20 formed on the base substrate 10, a circuit wiring 30 formed on the insulating resin layer 20 and including a via 31 and a circuit pattern 32, an organic surface treatment coating film 40 formed on the circuit wiring 30, and an insulating protective layer 50 formed on the organic surface treatment coating film 40.

The base substrate 10 is not particularly limited as long as it is made of a material with a predetermined strength or higher, and may be formed of polyethylene terephthalate (PET), polycarbonate (PC), polymethyl methacrylate (PMMA), polyethylene naphthalate (PEN), polyether sulfone (PES), cyclic olefin polymer (COC), triacetyl cellulose (TAC) film, polyvinyl alcohol (PVA) film, polyimide (PI) film, polystyrene (PS), biaxially oriented PS containing K resin; BOPS), glass, tempered glass, and the like.

Although the base substrate 10 is illustrated as a simple substrate, it is not limited thereto and may be an embedded substrate embedding various electrical and electronic components, or a substrate including a single or multiple electrical circuit wiring layers and a single or multiple insulating layers that embed and insulate the electrical circuit wiring layers.

The insulating resin layer 20 may be any one of an insulating film, a prepreg, and a build-up film, but is not limited thereto. In the case of the build-up film, it may be a build-up insulating film capable of forming a hydrogen bond with the organic surface treatment coating film 40 during a heat treatment process such as an Ajinomoto Build-up Film (ABF). In addition, the insulating film or the prepreg may include an insulating resin capable of forming a hydrogen bond with the organic surface treatment coating film 40 during a heat treatment process.

The insulating resin layer 20 may include an inorganic filler, a glass fiber, or a mixture thereof to improve the characteristics of the thermal expansion coefficient.

The inorganic filler is not particularly limited, but may be selected from, for example, silica (SiO₂), alumina (Al₂O₃), barium sulfate (BaSO₄), talc, mica powder, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), and calcium zirconate (CaZrO₃).

The glass fiber is not particularly limited, but may be one or more selected from, for example, E glass, T glass, S glass and NE glass. In addition, organic fibers such as, but not limited to, carbon fibers, polyparaphenylene benzobisoxazole fibers, thermotropic liquid crystal polymer fibers, lyotropic liquid crystal polymer fibers, aramid fibers, polypyridobisimidazole fibers, polybenzothiazole fibers, and polyarylate fibers may be used.

The circuit wiring 30 may include an electroless plating layer and an electroplating layer and may include copper (Cu) in consideration of economic aspects and electrical conductivity characteristics but is not particularly limited thereto.

The circuit wiring 30 may be formed by applying a method known as a printed circuit board manufacturing process such as a subtractive process, an additive process, a semi-additive process, and a modified semi-additive process (MSAP) method, but is not particularly limited thereto.

The organic surface treatment coating film 40 may include benzimidazole or a similar nitrogen-based heterocycle as a main component. The organic surface treatment coating film 40 may be an organic solderability preservative (“OSP”). Specifically, the organic surface treatment coating film 40 may include an imidazole-based alkoxy silane having a chemical structure of any one of Chemical Formula 1, Chemical Formula 2, Chemical Formula 3, Chemical Formula 4, and Chemical Formula 5.

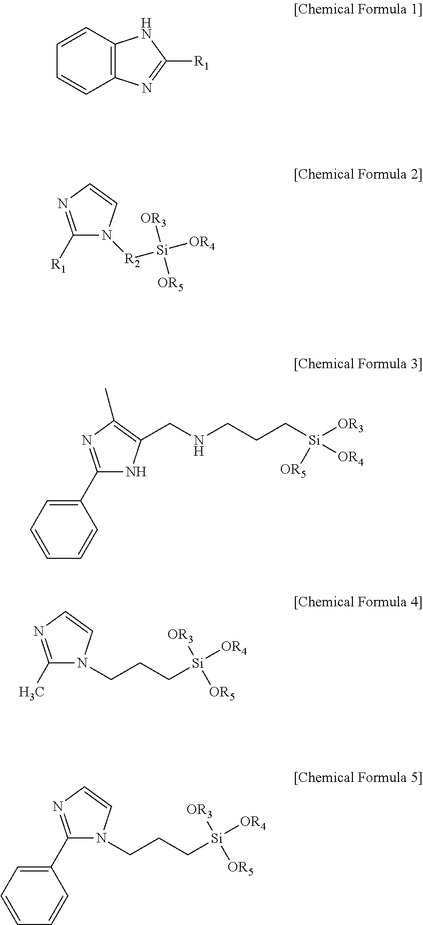

Here, the R₁ may be an alkyl group or an aryl group, the R₂ may be a C₁ to C₅ alkyl group with or without a heteroatom, and the R₃ to R₅ may be each independently H or CH₃.

In FIG. 3, the organic surface treatment coating film 40 is illustrated as covering an upper surface of the insulating resin layer 20 and a side and upper surface of the circuit pattern 32, but the organic surface treatment coating film 40 may also be disposed at least partially between the insulating resin layer 20 and the circuit pattern 32.

The insulating protective layer 50 may include a solder resist and may cover a portion of the circuit wiring 30. The remaining portion of the circuit wiring 30 may not be covered by the insulating protective layer 50.

The insulating resin layer 20, the circuit wiring 30, and the organic surface treatment coating film 40 may have improved mutual adhesion through chemical bond, such as coordinate bond between the circuit wiring 30 and the organic surface treatment coating film 40 and covalent bond (O—C═O bonding) between the insulating resin layer 20 and the organic surface treatment coating film 40. More specifically, an epoxy functional group of the insulating resin layer 20 and the imidazole of the organic surface treatment coating film 40 form a covalent bond, and the imidazole of the organic surface treatment coating film 40 and the copper of the circuit wiring 30 form a coordinate bond, thereby improving the adhesion between the insulating resin layer 20, the circuit wiring 30, and the organic surface treatment coating film 40.

Through this, the portion of the circuit wiring (30) that is not covered by the insulating protective layer 50 can be prevented from being separated or detached from the insulating resin layer 20.

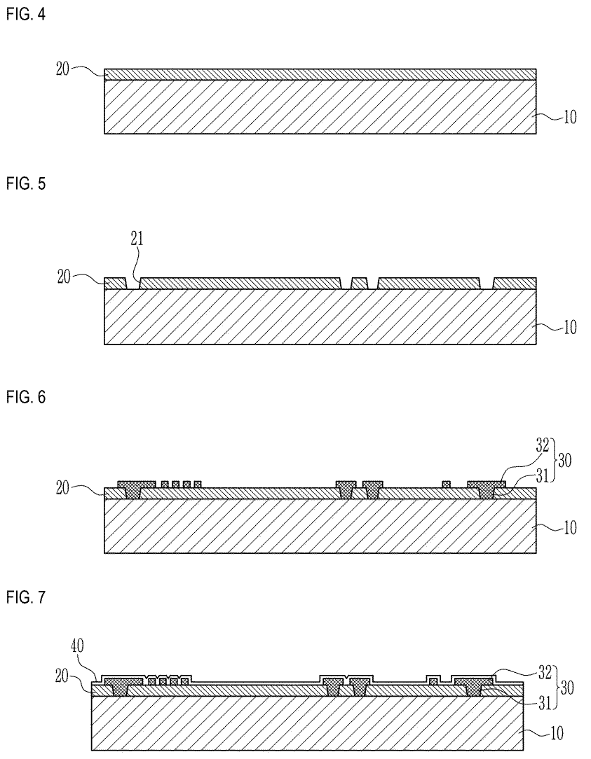

FIG. 4, FIG. 5, FIG. 6 and FIG. 7 are cross-sectional views schematically illustrating a method of manufacturing a printed circuit board according to an embodiment.

Referring to FIG. 4, the base substrate 10 is manufactured first. The base substrate 10 may be an embedded substrate embedding various electrical and electronic components, or a substrate including a single or multiple electrical circuit wiring layers and a single or multiple insulating layers that embed and insulate the electrical circuit wiring layers. In this case, various processes such as a process of forming a cavity in a substrate, a process of embedding an electrical and electronic component, a process of forming a circuit wiring layer, and a process of forming an insulating layer may be required, but these processes may be selectively adopted from among methods of manufacturing a printed circuit board known in the art, and thus a detailed description thereof is omitted.

The insulating resin layer 20 may be formed of an insulating film, a prepreg, or a build-up film on the base substrate 10. For example, ABF (Ajinomoto Build-up Film) is applied or placed, and a first curing may be performed to form the insulating resin layer 20 that is first cured. The first curing may be performed at a temperature of 100 °C to 200 °C.

Referring to FIG. 5, a via hole 21 may be formed in the insulating resin layer 20 that is first cured. The via hole 21 may be formed using a fine patterning method such as photolithography or a method such as laser or mechanical drilling.

Referring to FIG. 6, the circuit wiring 30 including an electroless plating layer and an electroplating layer may be formed on the insulating resin layer 20 which is first cured and via hole is formed in. The circuit wiring 30 may include copper (Cu), aluminum (Al), silver (Ag), tin (Sn), gold (Au), nickel (Ni), lead (Pb), titanium (Ti), and/or alloys thereof, and may preferably include copper (Cu). The circuit wiring 30 may be formed by applying a method known as a printed circuit board manufacturing process such as a subtractive process, an additive process, a semi-additive process, and a modified semi-additive process (MSAP) method, but is not particularly limited thereto.

A second curing may be performed on the insulating resin layer 20 on which the circuit wiring 30 is formed. The second curing may be performed at a temperature of 100 °C to 140 °C so that the epoxy functional group of the insulating resin layer 20 may remain and prevents separation due to a difference in coefficient of thermal expansion (CTE) between the insulating resin layer 20 and the circuit wiring 30. The second curing may be omitted. That is, after forming the circuit wiring 30 on the insulating resin layer 20 that is first cured, the organic surface treatment coating film 40 may be formed without an additional curing step.

Referring to FIG. 7, the organic surface treatment coating film 40 may be formed on the circuit wiring 30.

Surfaces of the circuit wiring 30 and the insulating resin layer 20 are cleaned, and a desmear treatment is performed to remove a contaminant layer and copper oxide, and then the organic surface treatment coating film 40 may be formed by immersing it in an aqueous solution of an imidazole derivative such as benzimidazole. At this time, a coordinate covalent bond (dative covalent bond) may be formed between the copper (Cu) of the circuit wiring 30 and the nitrogen N of the organic surface treatment coating film 40.

Before forming the organic surface treatment coating film 40, a routing process of dividing the base substrate 10 into four may be performed.

Thereafter, the substrate structure on which the organic surface treatment coating film 40 is formed may be further baked and the insulating protective layer 50 may be formed to manufacture the printed circuit board of FIG. 3. If the second curing is omitted, a greater number of epoxy residues may remain in the insulating resin layer 20, and thus more O—C═O bonds may be formed through baking after forming the organic surface treatment coating film 40.

After baking, processes such as singulation, electrical inspection, and screening of cutting into device units may be additionally required. The baking may be performed at a temperature of 100 °C to 200 °C.

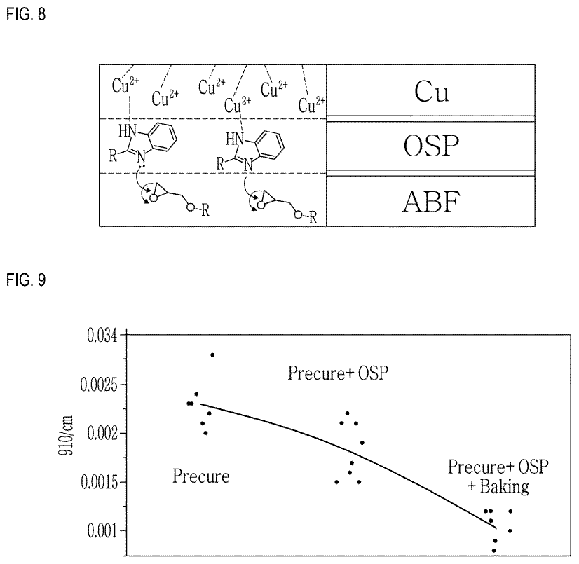

FIG. 8 is a conceptual view illustrating a chemical bond formed between an insulating resin layer, a circuit wiring, and a surface treatment coating film of a printed circuit board according to an embodiment.

According to the method of manufacturing a printed circuit board according to an embodiment, as illustrated in FIG. 8, the epoxy functional group of the insulating resin layer 20 and the imidazole of the organic surface treatment coating film 40 form a covalent bond, and the imidazole of the organic surface treatment coating film 40 and the copper of the circuit wiring 30 form a coordinate bond (dative covalent bond), thereby improving adhesion between the insulating resin layer 20, the circuit wiring 30, and the organic surface treatment coating film 40.

FIG. 9 is a graph illustrating that the remaining epoxy functional group decreases as the steps of a second curing of the insulating resin layer, formation of a surface treatment coating film, and baking treatment are performed.

As each step of the second curing of the insulating resin layer, formation of the surface treatment coating film, and the baking treatment is performed, the remaining epoxy functional groups decrease. This is because the epoxy functional groups of the insulating resin layer 20 and the imidazole of the organic surface treatment coating film 40 covalently bond to each other, thereby reducing the remaining epoxy functional groups.

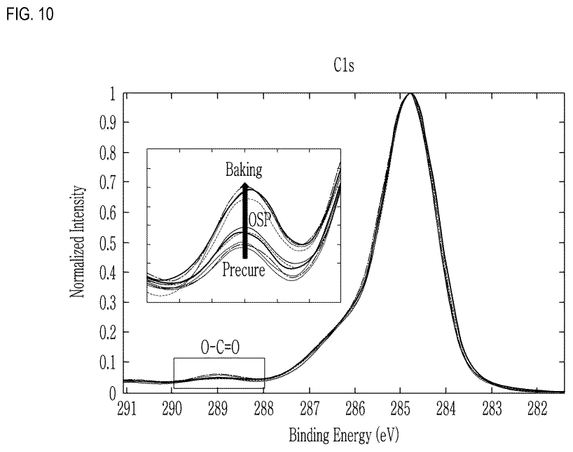

FIG. 10 is a graph illustrating that the O—C═O bond increases as the steps of a second curing of the insulating resin layer, formation of a surface treatment coating film, and baking treatment are performed.

Referring to FIG. 10, it may be seen that the covalent bond (O—C═O bond) between the insulating resin layer 20 and the organic surface treatment coating film 40 increases through the second curing of the insulating resin layer, formation of the surface treatment coating film, and the baking treatment.

The expression of the embodiment used herein does not mean the same embodiment but is provided to emphasize different unique features. However, the embodiments presented above do not preclude implementation in combination with features of another embodiment. For example, even if a description of a particular embodiment is not described in another embodiment, it can be understood as a description related to the other embodiment, unless there is a description that is contrary to or contradicts that description in the other embodiment.

The term used in the present disclosure is for the purpose of describing an embodiment only and is not intended to limit the disclosure. In this case, a singular expression includes a plural expression unless the context clearly indicates otherwise.

What is claimed is:

1. A method of manufacturing a circuit board comprising:
applying an insulating resin to form an insulating resin layer,
performing a first curing of the insulating resin layer,
forming a circuit wiring on the first cured insulating resin layer,
forming a surface treatment coating film by performing a surface treatment on the insulating resin layer and the circuit wiring, and
baking the insulating resin layer and the circuit wiring on which the surface treatment coating film is formed.

2. The method of claim 1, wherein the first curing is performed at a temperature of 100 °C to 200 °C, and the baking is performed at a temperature of 100 °C to 200 °C.

3. The method of claim 1, wherein an O—C═O bond is formed between the insulating resin layer and the surface treatment coating film through the baking.

4. The method of claim 1, wherein the insulating resin is ABF.

5. The method of claim 1, further comprising after the forming of the circuit wiring on the first cured insulating resin layer, performing a second curing on the insulating resin layer before the forming of the surface treatment coating film, wherein the second curing is performed at a temperature of 100 °C to 140 °C.

6. The method of claim 1, wherein the insulating resin layer comprises epoxy, the circuit wiring comprises copper (Cu), and the surface treatment coating film comprises imidazole.

7. The method of claim 6, wherein through the baking, a covalent bond is formed between an epoxy functional group of the insulating resin layer and the imidazole of the surface treatment coating film, and a coordinate bond is formed between copper of the circuit wiring and the imidazole of the surface treatment coating film.

8. The method of claim 1, further comprising after the baking, performing a singulation and conducting an electrical inspection.

9. The method of claim 8, further comprising after the forming of the circuit wiring on the first cured insulating resin layer, performing a routing before the performing of the surface treatment.

10. A circuit board comprising:
an insulating resin layer;
a circuit wiring disposed on the insulating resin layer;
a surface treatment coating film disposed on the insulating resin layer and the circuit wiring; and
wherein an O—C═O bond is formed between the insulating resin layer and the surface treatment coating film.

11. The circuit board of claim 10, wherein the insulating resin layer comprises epoxy, the circuit wiring comprises copper (Cu), and the surface treatment coating film comprises imidazole.

12. The circuit board of claim 11, wherein a covalent bond is formed between an epoxy functional group of the insulating resin layer and the imidazole of the surface treatment coating film, and a coordinate bond is formed between copper of the circuit wiring and the imidazole of the surface treatment coating film.

13. The circuit board of claim 10, wherein the insulating resin is ABF.

14. The circuit board of claim 13, wherein a covalent bond is formed between an epoxy functional group of the insulating resin layer and the imidazole of the surface treatment coating film, and a coordinate bond is formed between copper of the circuit wiring and the imidazole of the surface treatment coating film.

15. The circuit board of claim 10, wherein an insulating protective layer is disposed on the surface treatment coating film and covering a portion of the circuit wiring.

16. An electronic component package comprising: an insulating resin layer;
a circuit wiring disposed on the insulating resin layer;
a surface treatment coating film disposed on the insulating resin layer and the circuit wiring; and
wherein an O—C═O bond is formed between the insulating resin layer and the surface treatment coating film.

17. The electronic component package of claim 16, wherein the insulating resin layer comprises epoxy, the circuit wiring comprises copper (Cu), and the surface treatment coating film comprises imidazole.

18. The electronic component package of claim 17, wherein a covalent bond is formed between an epoxy functional group of the insulating resin layer and the imidazole of the surface treatment coating film, and a coordinate bond is formed between copper of the circuit wiring and the imidazole of the surface treatment coating film.

19. The electronic component package of claim 16, wherein the insulating resin is ABF.

20. The electronic component package of claim 16, wherein an insulating protective layer is disposed on the surface treatment coating film and covering a portion of the circuit wiring.
